(19) United States
(12) Patent Application Publication
(10) Pub. No.: US 2014/0363953 A1
(43) Pub. Date: Dec. 11, 2014

(54) METHOD FOR FORMING COMPONENTS ON A SILICON-GERMANIUM LAYER

(71) Applicant: STMicroelectronics S.A., Montrouge (FR)

(72) Inventor: Didier Dutartre, Meylan (FR)

(21) Appl. No.: 14/298,073

(22) Filed: Jun. 6, 2014

(30) Foreign Application Priority Data
Jun. 7, 2013 (FR) 1355246

(51) Int. Cl. H01L 27/092; H01L 29/78; H01L 29/66; H01L 21/762; H01L 29/16

(52) U.S. Cl. CPC H01L 27/092; H01L 21/7624; H01L 29/16; H01L 29/66477; H01L 29/78
USPC 438/479

(57) ABSTRACT

A method for manufacturing components on an SOI layer coated with a silicon-germanium layer formed by epitaxial deposition, wherein the heat balance of the anneals performed after the epitaxial deposition is such that the germanium concentration remains higher in the silicon-germanium layer than in the SOI layer.

### CROSS REFERENCE TO RELATED APPLICATIONS

This application claims the priority benefit of French Patent Application number 13/55246, filed on Jun. 7, 2013, entitled “Method For Forming Components On A Silicon-Germanium Layer”, the contents of which is hereby incorporated by reference in its entirety to the maximum extent allowable by law.

### BACKGROUND

1. Technical field

The present disclosure relates to the field of microelectronics, and more specifically to the forming of electronic components of small or very small dimensions on top and inside of an ultra-thin silicon-germanium layer laid on an electrically-insulating substrate. A component is here said to have very small dimensions when its smallest lateral dimension is smaller than 100 nanometers, for example, equal to 28 nm or 14 nm, and a layer is called ultra-thin when its thickness is smaller than 10 nm.

2. Discussion of the Related Art

It appears to be preferable to form certain electronic components on a silicon-germanium layer rather than on a silicon layer. Especially, in the case of CMOS circuits, it appears to be desirable, especially for components of very small dimensions, to form N-channel MOS transistors on silicon and P-channel MOS transistors on silicon-germanium.

One of the methods currently used to form, on a same silicon wafer, P-type components on silicon-germanium and N-type components on silicon will be described in relation with FIGS. 1A to 1C in the specific case of a structure of silicon-on-insulator or SOI type.

FIG. 1A shows a single-crystal silicon layer 1 formed on an insulating layer 2, currently silicon oxide, often called BOX (for Buried OXide) in the art. Insulating layer 2 is itself laid on a support 3, currently, in current technologies, a silicon wafer.

At the step illustrated in FIG. 1B, a layer 5 of silicon-germanium, Si₁₋ₓ₀Geₓ₀, that is, containing x0% of germanium, has been formed on silicon layer 1.

At the step illustrated in FIG. 1C, a thermal oxidation condensation method has been implemented. As a result, a silicon oxide layer 7 forms on the upper surface of the structure and the germanium concentrates in an intermediate layer 9 between layers 2 and 7 to form a silicon-germanium layer of homogeneous composition Si₁₋ₓGeₓ.

FIG. 2A shows the germanium concentration, x, according to depth Z in the various layers illustrated in FIG. 1B. In silicon-germanium layer 5, the germanium concentration is equal to x0. This concentration is zero in silicon layer 1 and in silicon oxide layer 2.

FIG. 2B shows the germanium concentration, x, according to depth Z in the various layers illustrated in FIG. 1C. In upper layer 7 made of SiO₂, this concentration is zero. It is equal to x1 in layer 9 and to 0 in insulating layer 2. Ratio x1/x0 is equal to the ratio of the thicknesses between layers 9 and 5 and depends on the duration of the oxidation anneal.

The applicant has observed that, when several P-channel MOS transistors are formed on layer 9 (after having removed insulating layer 7), these transistors have variable electric characteristics (threshold voltages and, correlatively, currents). This poses practical problems, especially in the context of the forming of analog circuits.

### SUMMARY

The inventor has analyzed the causes of such a threshold voltage dispersion and here provides a solution to this problem.

Thus, an embodiment provides a method for manufacturing components on an SOI layer coated with a silicon-germanium layer formed by epitaxial deposition, wherein the heat balance of the anneals performed after the epitaxial deposition is such that the germanium concentration remains higher in the silicon-germanium layer than in the SOI layer.

According to an embodiment, N-channel transistors are directly formed above the SOI layer and P-channel transistors are directly formed above the silicon-germanium on SOI layer.

According to an embodiment, the thickness of the silicon-on-insulator layer approximately ranges between 2 and 7 nm and the thickness of the epitaxial silicon-germanium layer approximately ranges between 3 and 7 nm.

### BRIEF DESCRIPTION OF THE DRAWINGS

The foregoing and other features and advantages will be discussed in detail in the following non-limiting description of specific embodiments in connection with the accompanying drawings.

FIGS. 1A to 1C, previously described, illustrate three successive steps of the forming of a silicon-germanium layer on SOI;

FIGS. 2A and 2B are curves of the germanium concentration in the structures of FIGS. 1B and 1C;

FIG. 3 shows MOS transistors formed on a silicon-germanium layer;

FIG. 4 shows the standard deviation of the threshold voltages for various thicknesses of a silicon-germanium layer formed by the process of FIGS. 1A to 1C;

FIG. 5 shows two portions of silicon-germanium layer formed according to the method described herein;

FIGS. 6A, 6B, 6C show germanium concentrations x according to depth Z at different steps of the forming of a structure of the type in FIG. 5;

FIGS. 7A, 7B, 7C show germanium concentrations x according to depth Z at different steps of the forming of a structure of the type in FIG. 5; and

FIG. 8 shows the standard deviation of the threshold voltages for structures such as described herein.

For clarity, the same elements have been designated with the same reference numerals in the different drawings and, further, as usual in the representation of integrated circuits, the various drawings are not to scale.

### DETAILED DESCRIPTION

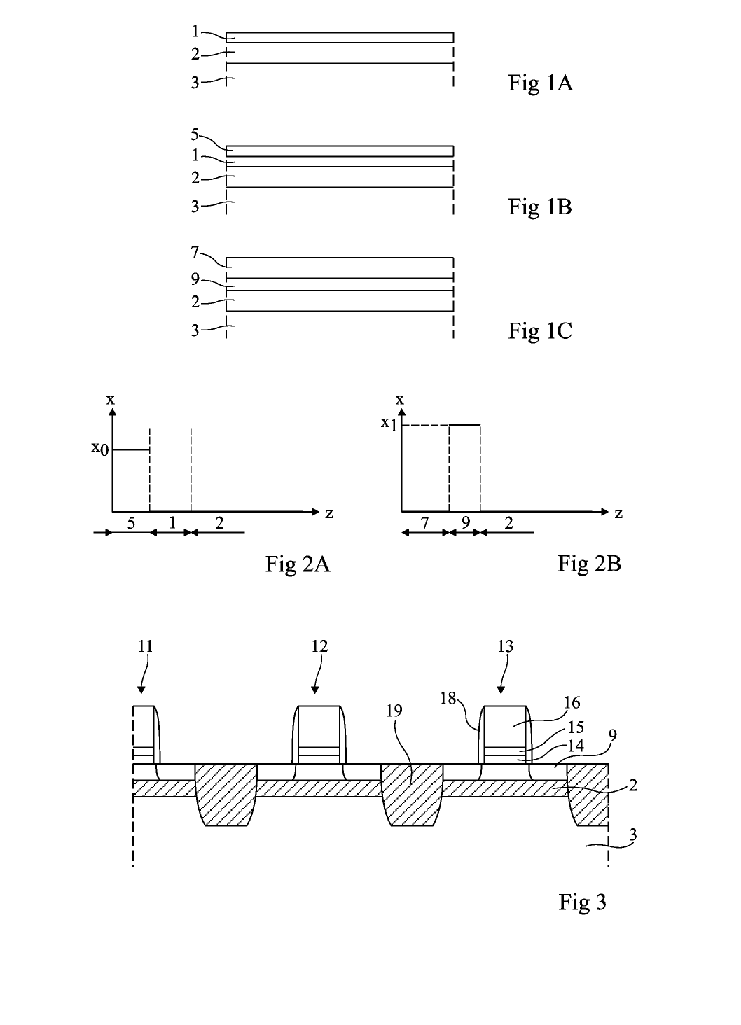

FIG. 3 shows three P-channel MOS transistors 11, 12, and 13 formed on a silicon-germanium 9 such as that obtained at the step described in relation with FIG. 1C, after elimination of upper SiO₂ layer 7. The gate of each MOS transistor has been shown as being formed of an insulating layer 14, preferably made of an insulator of high dielectric constant, coated with a metal layer 15 itself coated with a polysilicon layer 16, the gate being surrounded with one or several spacers 18. The transistors are separated by trenches filled with insulator 19 which cross silicon-germanium layer 9. In current embodiments, the gate length may be smaller than 30 nm. At such a scale, the surface unevennesses of silicon-on-insulator layer 1, which affect silicon-germanium layer 5 and then final layer 9, are such that it can be considered that the silicon-germanium thickness under the gate of each transistor is capable of varying from one transistor to the other. It should be understood that such a thickness variation also results in a variation of germanium content x in the silicon-germanium. The inventors have calculated the influence of such a thickness variation on the transistor threshold voltage.

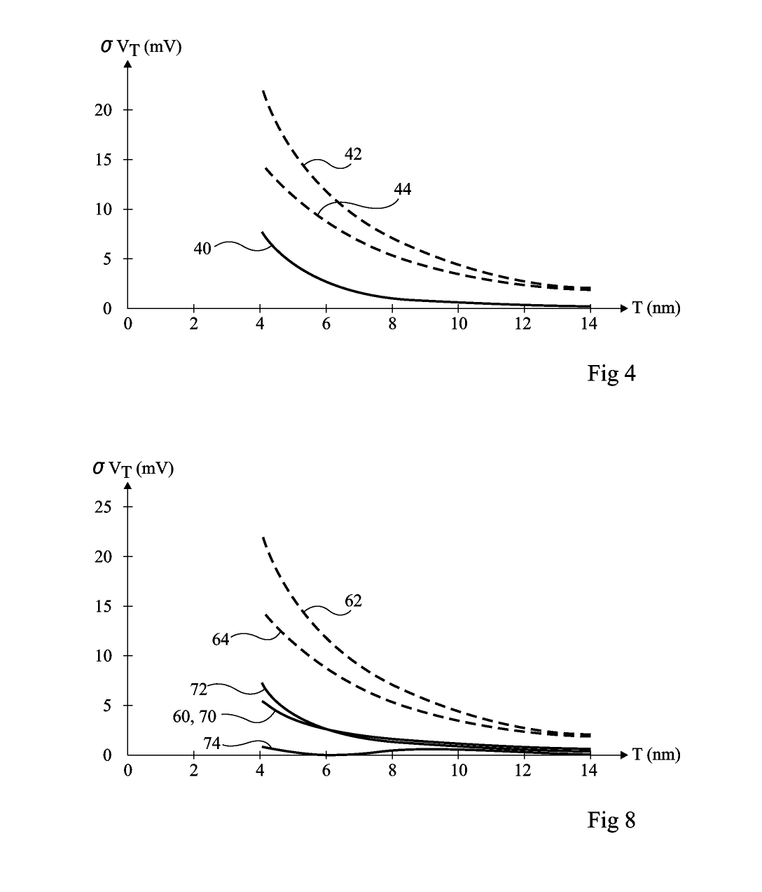

The result of such calculations performed for long transistors and with a given thickness variability (but also valid for short transistors with an improved variability) is illustrated in FIG. 4, where curve 40 indicates the variation of standard deviation σV_{T} in millivolts of threshold voltages V_{T} of the transistors according to thickness T of the SiGe layer in a thickness range from 4 to 14 nm. Curve 42 indicates standard deviation σV_{T} according to the variations of concentration x which are, as previously indicated, correlated to the thickness variations. Curve 44 is the resultant of these two effects. It should be noted that the two effects have opposite signs. When thickness T decreases, the threshold voltage tends to increase and, similarly, when thickness T decreases, germanium concentration x increases and the threshold voltage tends to decrease. Thus, curve 44 substantially corresponds to the difference between curves 40 and 42.

This threshold voltage variation for the different transistors formed on the silicon-germanium layer appears to be inherent to the previously-described method for manufacturing the silicon-germanium layer.

A novel method for forming the silicon-germanium layer which enables to overcome these disadvantages is thus provided herein.

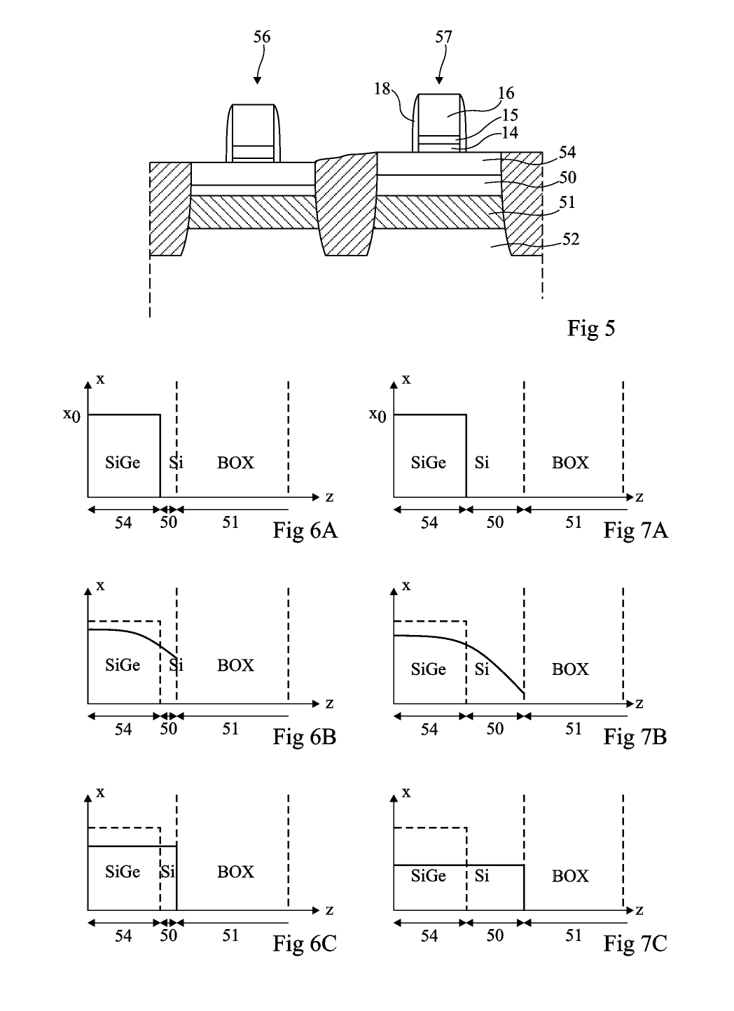

As illustrated in FIG. 5, it is started, as previously discussed, from a silicon layer 50 formed on an insulator 51, itself formed on a support. Insulator 51 currently is silicon oxide and support 52 currently is a silicon wafer. On layer 50, a silicon-germanium layer 54 of composition Si₁₋ₓ₀Geₓ₀ has been formed by epitaxy.

Two transistors 56 and 57 are formed on two portions of SiGe layer 54. The elements of their gates are designated with the same reference numerals as in FIG. 3. Layer 50 of left-hand transistor 56 has been shown, with exaggerated dimensions, as being thinner than layer 50 of right-hand transistor 57. The epitaxy method is such that silicon-germanium layer 54 has a constant thickness. Its upper surface of course reproduces thickness unevennesses of underlying silicon layer 50.

After the epitaxy, an anneal such that the germanium contained in silicon-germanium layer 54 only partially diffuses into silicon layer 50 is performed.

FIGS. 6A, 6B, and 6C illustrate germanium concentration x in the various layers of a transistor for which underlying silicon layer 50 has a “minimum” thickness. FIGS. 7A, 7B, and 7C illustrate the case where the silicon layer has a “maximum” thickness. It should be understood that terms “minimum” and “maximum” correspond to the extreme thickness fluctuations inherent to the manufacturing of silicon layer 50.

For a better understanding of the phenomena which are desired to be explained herein, the thickness variations have been very exaggerated between FIGS. 6 and FIGS. 7, in the same way as to the right and to the left of FIG. 5. In practice, the thickness of silicon layer 50 is initially on the order of 10 nm and it is here provided to thin it down, for example by oxidation and removal of the oxide, so that it only has a thickness on the order of from 2 to 7 nm, for example, 4 nm. It should be clear that after oxidation and removal of the oxide, the silicon layer keeps its thickness unevennesses. These may approximately range from 0.5 to 1.5 nm. The epitaxial silicon-germanium layer has a thickness approximately ranging from 3 to 7 nm, for example, 4 nm.

FIGS. 6A and 7A show that, initially, before any anneal, the silicon-germanium layer has a germanium concentration x0. FIGS. 6B and 7B show the course of the variation of x when only a slight anneal of the structure is performed. The silicon concentration decreases from the upper surface of silicon-germanium layer 54 all the way to the lower surface of silicon layer 50. The germanium concentration decreases less in layer 54 in the case where silicon-on-insulator layer 50 is thin (transistor 56) than in the case where it is thick (transistor 57). However, this variation is low at the level of the upper surface of layer 54.

FIGS. 6C and 7C illustrate, as a comparison, the case where the anneal is continued until the germanium evenly distributes in the initial silicon-germanium layer and in the initial silicon-on-insulator layer. It can be seen in this case that the general concentration variation in the structure, and especially at the level of silicon-germanium layer 54, is much larger if only partial anneals are performed.

In FIG. 8, curves 60, 62, and 64 correspond to the cases of FIGS. 6C and 7C, that is, with a germanium concentration which is totally homogenized in the initial silicon-on-insulator layer 50 and epitaxial silicon-germanium layer 54. Curve 60 indicates the variation of standard deviation σV_{T} in millivolts according to thickness T of the SiGe layer. Curve 62 indicates standard deviation σV_{T} according to concentration x which is, as previously indicated, correlated to the thickness variations. Curve 64 illustrates the resultant of these two effects. Curve 64 substantially corresponds to the difference between curves 60 and 62.

In FIG. 8, curves 70, 72, and 74 correspond to the case of FIGS. 6B and 7B, that is, with a germanium concentration which is not homogenized in the initial silicon-on-insulator layer 50 and epitaxial silicon-germanium layer 54. Curve 70 represents standard deviation σV_{T} in millivolts according to thickness T. Curve 72 represents standard deviation σV_{T} according to concentration x. Curve 74 illustrates the resultant of these two effects.

The curves of FIG. 8 illustrate the fact that only providing a partial anneal to be in the situation of FIGS. 6B and 7B considerably decreases the standard deviation σV_{T} of threshold voltages V_{T} of the transistors formed on silicon-germanium layer 54.

In the case of FIGS. 6C and 7C, that is, when the silicon-germanium concentration is totally homogenized in initial silicon-on-insulator layer 50 and epitaxial silicon-germanium layer 54, the curve of standard deviation 60 versus thickness and the curve of standard deviation 62 versus germanium concentration x are substantially identical to curves 40 and 42 of FIG. 4. Resultant 64 is substantially identical to resultant 44 illustrated in FIG. 4.

However, in the case illustrated in FIGS. 6B and 7B, curves 60, 62, and 64 respectively become curves 70, 72, and 74. In other words, the curve of the value of the standard deviation of the threshold voltages versus thickness does not substantially vary. This means that the presence of a lightly-doped germanium layer under a more heavily-doped layer has no influence upon the operation. However, the curve of the standard deviation of the threshold voltage versus the germanium concentration of the initially-formed epitaxial layer considerably decreases and becomes very close to the curve of the variation of the standard deviation versus thickness. Given that these two contributions to the standard deviation subtract from each other, resultant 74 constantly remains close to zero, that is, the threshold voltage of the MOS transistors formed on the epitaxial silicon-germanium layer becomes practically insensitive to thickness variations inherent to the forming of the silicon-on-insulator layer.

Thus, it is here provided to select all the steps which necessitate a thermal treatment so that they do not cause too significant a diffusion of the germanium of an epitaxial silicon-germanium layer in a silicon-on-insulator base layer so that the germanium concentration remains higher in the epitaxial layer than in the SOI layer. In other words, the SOI thickness under the epitaxy and the subsequent thermal budget are adjusted so that the diffusion depth of Ge into Si is of the order of magnitude, to within a factor 3, of the SOI thickness before epitaxy.

In practice, it will be within the abilities of those skilled in the art, according to the thicknesses desired for the SOI layer and the silicon-germanium layer, which should further be as low as possible to optimize the operation of MOS transistors, to optimize the total heat balance so that the curve of variation of the standard deviation versus the silicon-germanium thickness and the curve of variation of the standard deviation versus the silicon-germanium concentration are as close as possible. This may be achieved by the use of well-known simulation programs.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for manufacturing components on an SOI layer coated with a silicon-germanium layer formed by epitaxial deposition, wherein the heat balance of the anneals performed after the epitaxial deposition is such that the germanium concentration remains higher in the silicon-germanium layer than in the SOI layer.

2. The method of claim 1, wherein N-channel transistors are directly formed above the SOI layer and P-channel transistors are directly formed above the silicon-germanium on SOI layer.

3. The method of claim 1, wherein the thickness of the SOI layer approximately ranges between 2 and 7 nm and the thickness of the epitaxial silicon-germanium layer approximately ranges between 3 and 7 nm.
